(19) United States
(12) Patent Application Publication
(10) Pub. No.: US 2022/0402057 A1
(43) Pub. Date: Dec. 22, 2022

(54) Magnetic-field melting solder, and joining method in which same is used

(71) Applicants: SENJU METAL INDUSTRY CO., LTD., Tokyo (JP); National Institute of Advanced Industrial Science and Technology, Tokyo (JP)

(72) Inventors: Haruya SAKUMA, Tokyo (JP); Kenichi TOMITSUKA, Tokyo (JP); Hisahiko YOSHIDA, Tokyo (JP); Kenji KANAZAWA, Ibaraki (JP); Sei UEMURA, Ibaraki (JP); Takashi NAKAMURA, Miyagi (JP); Masateru NISHIOKA, Miyagi (JP)

(73) Assignees: SENJU METAL INDUSTRY CO., LTD., Tokyo (JP); National Institute of Advanced Industrial Science and Technology, Tokyo (JP)

(21) Appl. No.: 17/779,801

(22) PCT Filed: Nov. 18, 2020
(86) PCT No.: PCT/JP2020/043050

§ 371 Date: May 25, 2022

(30) Foreign Application Priority Data
Nov. 26, 2019 (JP) 2019-213372

(51) Int. Cl. B23K 1/002; B23K 35/02; B23K 35/26

(52) U.S. Cl. CPC B23K 1/002; B23K 35/0205; B23K 35/26; B23K 2101/42

(57) ABSTRACT

A magnetic-field melting solder that melts by the action of an AC magnetic field is provided. The magnetic-field melting solder includes solder material; and magnetic material composing of ferrite or Ni, a proportion of the magnetic material to the entire magnetic-field melting solder being 0.005% to 5% by weight. A joining method using the magnetic-field melting solder includes providing the magnetic-field melting solder between an electrode on a substrate and an electrode of an electronic component, and joining together the electrode on the substrate and the electrode of the electronic component by generating an AC magnetic field around the substrate and thereby melting the magnetic-field melting solder.

### FIELD

The present invention relates to solder that melts by the action of an AC magnetic field and to a joining method using the preform solder.

### BACKGROUND

PTL 1 discloses a solder joint containing magnetic particles. This solder joint is obtained by the following method. First, a mixture of solder material and magnetic particles are heated. Consequently, a molten matrix of solder particles is formed. Next, a magnetic field is applied around the molten matrix. Upon application of the magnetic field, unmolten magnetic particles are aligned along a direction of the magnetic field. Next, the molten matrix is cooled. The cooling of the molten matrix is done during, or upon completion of, application of the magnetic field. Consequently, a solder joint with magnetic particles being arranged in a solder matrix is obtained.

PTL 2 discloses a microwave heating device. The heating device generates a microwave as a specific standing wave in a cavity resonator. The heating device keeps the distribution of an electric field and magnetic field in the cavity resonator in a desired state through adjustment of microwave frequency. When the distribution of the electric field and magnetic field is kept in a desired state, a region extremely low in electric field intensity and high in magnetic field intensity is created at the position of the central axis of the cavity resonator. Furthermore, the heating device conveys an object to be heated through this region. The object to be heated is heated by a magnetic field component of the microwave without being affected by the electric field component of the microwave. Note that examples of the object to be heated include an electrode pattern with solder placed thereon.

### CITATION LIST

### Patent Literature

[PTL 1] JP H6-277871 A
[PTL 2] JP 2019-136771 A

### SUMMARY

### Technical Problem

The reason why the magnetic field is applied in PTL 1 is that arrangement of magnetic particles is effective in improving mechanical properties of the solder joint. Thus, in PTL 1, the solder material is melted before application of the magnetic field. In this regard, in PTL 2, a magnetic field is applied to heat an object to be heated. Therefore, the technique in PTL 1 and the technique in PTL 2 differ from each other in the purpose of use and timing of application of the magnetic field.

The technique described in PTL 2, can melt solder by heating the solder directly or indirectly by the action of the magnetic field component. However, the technique described in PTL 2 is characterized by control over the distribution of an electric field and magnetic field. Therefore, discussions from the viewpoint of the “solder” to be melted are needed.

An object of the present invention is to provide novel solder that can melt by the action of a magnetic field and a joining method using the solder.

### Solution to Problem

As a result of diligent studies in view of the above problems, the present inventors have found that when an AC magnetic field is applied solder material to which magnetic material is added, a rate of temperature rise of the solder material can be increased. The present inventors also have found that this effect can be obtained while suppressing the influence on a joining function of the solder by setting a ratio of the magnetic material to the entire solder within a predetermined range. The present invention has been completed by the studies repeatedly performed based on these findings.

A first invention is a magnetic-field melting solder that melts by action of an AC magnetic field and has the following features.

The magnetic-field melting solder comprising solder material and magnetic material, a proportion of the magnetic material to the entire magnetic-field melting solder being 0.005 to 20% by weight.

A second invention further has the following feature in the first invention.

An upper limit of the proportion is 5% by weight.

A third invention further has the following feature in the second invention.

An upper limit of the proportion is 0.9% by weight.

A fourth invention has the following feature in any one of the first to third inventions.

The magnetic material is ferromagnetic material.

A fifth invention has the following features in any one of the first to fourth inventions.

The magnetic-field melting solder further comprising a solder layer containing the solder material and a magnetic layer containing the magnetic material by being provided on a surface of the solder layer.

A sixth invention has the following features in any one of the first to fourth inventions.

The magnetic-field melting solder further comprising solder particles containing the solder material and magnetic particles containing the magnetic material by being provided inside the solder particles.

A seventh invention has the following features in any one of the first to fourth inventions.

The magnetic-field melting solder further comprising flux.

An eighth invention is a joining method using the magnetic-field melting solder according to any one of the first to seventh inventions.

The joining method comprising the steps of:

providing the magnetic-field melting solder between an electrode on a substrate and an electrode of an electronic component; and

joining together the electrode on the substrate and the electrode of the electronic component by generating an AC magnetic field around the substrate and thereby melting the magnetic-field melting solder.

### Advantageous Effects of Invention

Solder material and magnetic particles generate heat by the action of an AC magnetic field. However, the magnetic particles, which generate heat quickly by the action of the AC magnetic field, heat the surrounding solder material. Consequently, the heat generation by the action of the AC magnetic field and heating by the surrounding magnetic particles facilitate rises in the temperature of the solder material. The present invention is magnetic-field melting solder that includes solder material and magnetic particles. Thus, the present invention makes it possible to melt solder material in a short time.

However, contribution of magnetic material to the original joining function of the solder is small, and too large a proportion of the magnetic material will obstruct an original joining function of the solder material. In this regard, with the magnetic-field melting solder according to the present invention, the proportion of the magnetic material to the entire solder is 0.005% to 30% by weight. Thus, the joining time can be reduced while reducing the impact on the joining function.

The joining method according to the present invention can join together the electrode on a substrate and the electrode of an electronic component by melting the magnetic-field melting solder according to the present invention using the AC magnetic field generated around the substrate. That is, the present invention makes it possible to melt the magnetic-field melting solder in a short time using an AC magnetic field generated locally and thereby electrically connect the electrodes to each other. This in turn makes it possible to join together the electrodes while minimizing an impact imposed on the substrate and the electronic component.

### BRIEF DESCRIPTION OF DRAWINGS

FIG. 1 is a schematic sectional view of a solder preform resulting from application of a solder according to an embodiment;

FIG. 2 is a schematic sectional view of a solder ball resulting from application of a solder according to the embodiment;

FIG. 3 is a schematic sectional view of a solder paste resulting from application of a solder according to the embodiment;

FIG. 4 is a diagram showing an example of a first joining method using the solder according to the embodiment; and

FIG. 5 is a diagram showing an example of a second joining method using the solder according to the embodiment.

### DESCRIPTION OF EMBODIMENTS

First, solder according to an embodiment of the present invention will be described. Note that when a numerical value range is indicated by “to,” the values at the upper and lower ends are included in the range as the lower and upper limits.

### 1. Magnetic-Field Melting Solder

The solder according to the present embodiment is the magnetic-field melting solder that melts by the action of an AC magnetic field. The solder according to the present embodiment contains magnetic material and solder material.

### 1.1 Magnetic Material

The magnetic material has the property of generating heat due to at least hysteresis losses when placed in an AC magnetic field. The reason for the reference to “at least hysteresis losses” is that eddy-current losses are conceivable. When the magnetic material is a conductor, the magnetic material generates heat due to hysteresis losses and eddy-current losses. The magnetic material is not specifically limited. For example, one metal selected from among ferromagnetic metal, paramagnetic metal, and diamagnetic metal can be used as the magnetic material.

Examples of the ferromagnetic metal include Ni, Co, Fe, Gd, and Tb. Examples of the paramagnetic metal include Y, Mo, and Sm. Examples of the diamagnetic metal include Cu, Zn, and Bi. Examples of the magnetic material include an alloy, an oxide, or a nitride containing at least one of the metals mentioned above. Examples of ferromagnetic metal oxides include Fe₃O₄, γ-Fe₂O₃, and ferrite composed principally of Fe₃O₄. Examples of paramagnetic metal oxides include Nd₂O₃, Tb₃O₄, and Sm₂O₃. Examples of diamagnetic metal oxides include CoO, NiO, α-Fe₂O₃, and Cr₂O₃. Examples of ferromagnetic metal nitrides include Fe₃N.

The stronger the magnetism of the magnetic material, the larger the hysteresis losses. Increases in hysteresis losses result in an increased amount of generated heat per unit time. The increased amount of generated heat per unit time facilitates heating of the surroundings by the magnetic material. Thus, from the viewpoint of facilitating heating by the magnetic material, preferably the magnetic material has ferromagnetism. Specifically, it is preferable to select at least one magnetic material from ferromagnetic metals, oxides and nitrides of the ferromagnetic metals, ferromagnetic alloys, and oxides and nitrides of the ferromagnetic alloys.

The proportion of the magnetic material is 0.005% to 20% by weight (wt %). The proportion is calculated with reference to the entire magnetic-field melting solder. The reason why the upper limit is set to 20% by weight is that a value larger than 20% by weight will make it difficult for the solder in a molten state to cohere and will obstruct an original joining function of the solder. From the viewpoint of reducing the impact on the joining function, preferably the upper limit is 5% by weight, more preferably 0.9% by weight, and still more preferably 0.5% by weight.

### 1.2 Solder Material

The solder material has the property of generating heat due to at least eddy-current losses when placed in an AC magnetic field. The reason for the reference to “at least eddy-current losses” is that hysteresis losses are conceivable. When solder material has magnetism, the solder material generates heat due to eddy-current losses and hysteresis losses. When the solder material generates heat with its temperature exceeding the melting point (which refers to solidus temperature or liquidus temperature; the same applies hereinafter), the solder material melts.

The magnetic material placed in the AC magnetic field generates heat and rises in temperature more quickly than the solder material. Therefore, when the solder material is placed in the same AC magnetic field as the magnetic material, the solder material is heated by the surrounding magnetic material. That is, when the solder material and the magnetic material are placed in the same AC magnetic field, the rate of temperature rise increases compared to when the solder material is placed singly in the AC magnetic field and the melting point is exceeded in a shorter time.

The solder material is not specifically limited and any of various types of solder alloy can be used. The various types of solder alloy include binary alloys and ternary and further multi-element alloys. Examples of the binary alloys include Sn—Sb alloys, Sn—Pb alloys, Sn—Cu alloys, Sn—Ag alloys, Sn—Bi alloys, and Sn—In alloys. Examples of the multi-element alloys include alloys produced by adding one or more metals selected from the group consisting of Sb, Bi, In, Cu, Zn, As, Ag, Cd, Fe, Ni, Co, Au, Ge, and P to any of the binary alloys described above.

### 1.3 Flux

The solder according to the present embodiment contains flux as an optional component. The flux is not specifically limited, and a typical flux may be used. The flux includes a resin (base resin), a solvent, and various additives. Examples of the resin include rosin-based resins, acrylic resins, polyester, polyethylene, polypropylene, polyamide, epoxy resins, and phenol resins. Examples of the solvent include alcohols such as ethanol, isopropyl alcohol, and butanol; hydrocarbons such as toluene and xylene; esters such as isopropyl acetate and butyl benzoate; and glycol ethers such as ethyleneglycol and hexyl diglycol. Examples of the various additives include activators, thixotropic agents, antioxidants, surface active agents, antifoaming agents, and corrosion inhibitors.

When the solder according to the present embodiment contains a flux, there is no particular limit to the proportion of the flux to the entire magnetic-field melting solder. The proportion of the flux is, for example, 5% to 95% by weight.

### 2. Concrete Examples of Magnetic-Field Melting Solder

### 2.1 Solder Preform

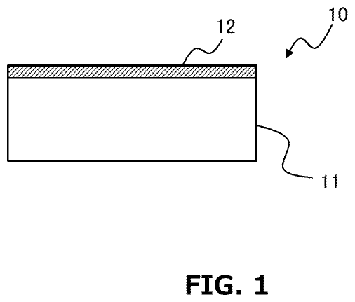

The solder according to the present embodiment is applied to solder preforms. Examples of shapes of solder preforms include a ribbon shape, a disk shape, a washer shape, a chip shape, and a ring shape. FIG. 1 is a schematic sectional view of a solder preform 10 resulting from application of the solder according to the present embodiment. As shown in FIG. 1, the solder preform 10 includes a solder layer 11 and a magnetic layer 12.

The solder layer 11 contains the solder material, but does not contain the magnetic material. The solder layer 11 is a typical solder preform manufactured by a method generally known in the solder industry. The flux may be included inside the solder layer 11. The flux is not specifically limited, and any of various types of flux is used. A surface of the solder layer 11 may be coated with the flux.

The magnetic layer 12 is provided on the surface of the solder layer 11. The magnetic layer 12 contains the magnetic material and a binder, but does not contain the solder material. The magnetic layer 12 is formed by applying a mixture of magnetic material and the binder to the surface of the solder layer 11. The binder is not specifically limited as long as the binder keeps the magnetic layer 12 from separating from the solder layer 11. Examples of the binder include flux.

### 2.2 Solder Ball

The solder according to the present embodiment is also applied to solder balls. Solder balls are used, for example, for semiconductor packages such as BGAs (ball grid arrays). The solder balls are manufactured by a method generally known in the solder industry.

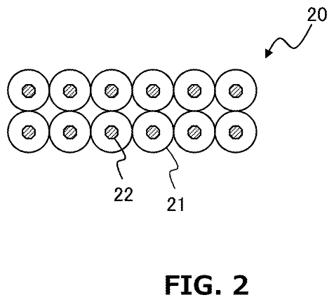

FIG. 2 is a schematic sectional view of solder balls 20 resulting from application of the solder according to the present embodiment. As shown in FIG. 2, each of the solder balls 20 contains a solder particle 21 and a magnetic particle 22. The solder particle 21 contains the solder material, but does not contain the magnetic material. The surfaces of the solder particle 21 may be coated with flux. The flux is not specifically limited, and any of various types of flux is used. The magnetic particle 22 is provided inside the solder particle 21. That is, the magnetic particle 22 makes up a core of the solder ball 20. The magnetic particle 22 contains the magnetic material, but does not contain the solder material.

### 2.3 Solder Paste

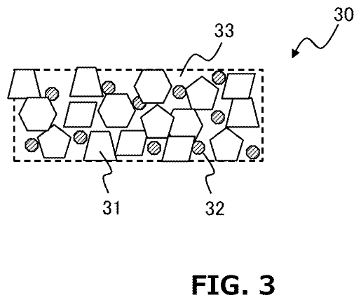

The solder according to the present embodiment is also applied to solder paste. FIG. 3 is a schematic sectional view of solder paste 30 resulting from application of the solder according to the present embodiment. As shown in FIG. 3, the solder paste 30 contains solder particles 31, magnetic particles 32, and flux 33. The solder particles 31 contain solder material, but do not contain magnetic material. The magnetic particles 32 contain magnetic material, but do not contain solder material. The flux 33 is added as a binder between the solder particles 31 and the magnetic particles 32. The flux 33 is not specifically limited, and any of various types of flux is used.

### 3. Examples of Joining Method Using Magnetic-Field Melting Solder

### 3.1 Joining Using Induction Heating Device

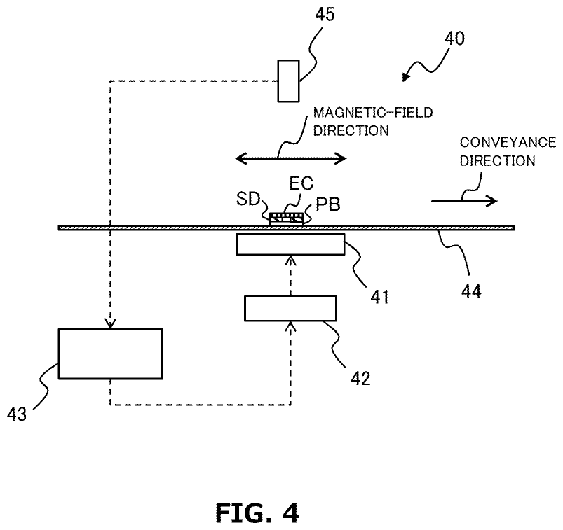

FIG. 4 is a diagram showing an example of a first joining method using the solder according to the present embodiment. An induction heating device 40 shown in FIG. 4 includes a heating coil 41, an inverter circuit 42, a control circuit 43, a conveyer 44, and a temperature sensor 45. Note that the solder according to the present embodiment is placed between an electronic component EC and a printed board PB as “solder SD” for use to join together an electrode of the electronic component EC and an electrode pattern printed on the printed board PB. Examples of the electronic component EC include an IC chip.

The heating coil 41 is provided behind the conveyer 44. The heating coil 41 heats an entire circuit board CB including the solder SD by induction heating. By being supplied with electric power from an AC power source (not shown), the inverter circuit 42 supplies high frequency current to the heating coil 41. The control circuit 43 is made up of a microcomputer. The control circuit 43 controls driving of the inverter circuit 42 based on various signals inputted to the control circuit 43. The various signals include a drive request signal and a signal that indicates the temperature around the circuit board CB. The conveyer 44 conveys the circuit board CB. The temperature sensor 45 detects the temperature around the circuit board CB. The temperature sensor 45 may generate temperature distribution information by image processing.

In the example shown in FIG. 4, as the conveyer 44 is driven, the circuit board CB is conveyed to the position of the heating coil 41. The conveyance of the circuit board CB is stopped at this position, and the inverter circuit 42 is driven based on the drive request signal. Consequently, an AC magnetic field is generated around the circuit board CB, and the magnetic material contained in the solder SD generates heat due to eddy-current losses and hysteresis losses. Besides, the solder material of the solder SD melts as a result of heat generation caused by eddy-current losses as well as heating by the magnetic material. That is, the solder SD melts. When an ending condition is satisfied, the driving of the inverter circuit 42 is stopped, or the circuit board CB is conveyed to outside the position of the heating coil 41 as the conveyer 44 resumes being driven. Subsequently, as the solder SD is cooled, the electrode of the electronic component EC and the electrode pattern are electrically connected to each other. Note that the ending condition is, for example, that a predetermined period of time elapses after the temperature around the circuit board CB reaches the melting point of the solder SD.

3.2 Joining by Microwave Heating Device

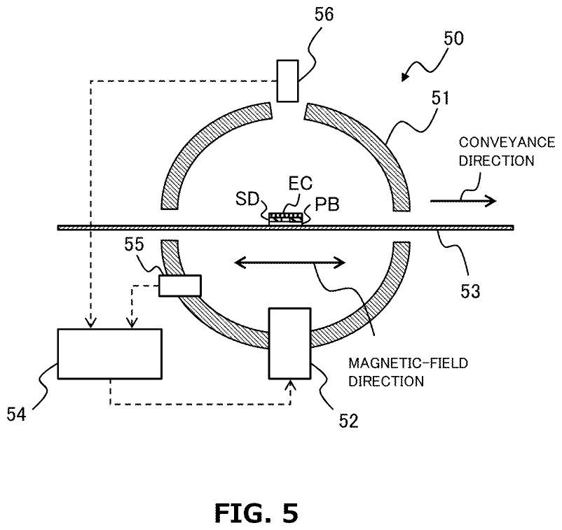

FIG. 5 is a diagram showing an example of a second joining method using the solder according to the present embodiment. A microwave heating device 50 shown in FIG. 5 includes a cavity resonator 51, a microwave feeder 52, a conveyer 53, a controller 54, an electromagnetic wave sensor 55, and a temperature sensor 56. Note that as with the example shown in FIG. 4, the solder according to the present embodiment is placed between the electronic component EC and the printed board PB.

The cavity resonator 51 has a cylindrical interior space in which microwave irradiation is performed. The microwave feeder 52 generates a microwave as a specific standing wave in the interior space. Examples of the specific standing wave include a standing wave called TM110. The conveyer 53 conveys the circuit board CB by passing through the interior space. Based on various signals, the controller 54 adjusts the frequency of the microwave emitted from the microwave feeder 52. The various signals include a drive request signal, a signal indicating the resonance status of the standing wave generated in the interior space, and a signal indicating the temperature around the circuit board CB. The electromagnetic wave sensor 55 detects the resonance status of the standing wave. The temperature sensor 56 detects the temperature around the circuit board CB. The temperature sensor 56 may generate temperature distribution information by image processing.

In the example shown in FIG. 5, the controller 54 drives the microwave feeder 52 based on the drive request signal. The controller 54 calculates a target value (target frequency) of oscillation frequency of the microwave based on the signal indicating the resonance status of the standing wave and the controller 54 outputs the target value to the microwave feeder 52. When it is verified that a standing wave has been formed, the conveyer 53 is driven and the circuit board CB is conveyed to a specific position in the cavity resonator 51. Examples of the specific position include the position of a central axis of the interior space. The target frequency is calculated repeatedly by the controller 54 during the conveyance of the circuit board CB. As the target frequency is calculated repeatedly, a region extremely low in electric field intensity and high in magnetic field intensity is created at the specific position.

When the circuit board CB passes the specific position, an AC magnetic field being generated at this position acts on the circuit board CB. Consequently, the magnetic material contained in the solder SD generates heat due to eddy-current losses and hysteresis losses. Besides, the solder material of the solder SD melts as a result of heat generation caused by eddy-current losses as well as heating by the magnetic material. That is, the solder SD melts. When the ending condition is satisfied, the driving of the microwave feeder 52 is stopped, or the circuit board CB is conveyed to outside the microwave feeder 52 as the driving of the conveyer 53 is resumed. Subsequently, as the solder SD is cooled, the electrode of the electronic component EC and the electrode pattern are electrically connected to each other. Based on the signal indicating the temperature around the circuit board CB, the controller 54 adjusts microwave output. For example, when the temperature around the circuit board CB reaches a predetermined temperature, the controller 54 reduces output. As another example, the closer the temperature around the circuit board CB is to the melting point of the solder SD, the more greatly the controller 54 reduces output.

### 4. EXAMPLES

Next, the present invention will be described in detail below with reference to Examples.

### 4.1 Example 1

Sample paste was prepared by mixing solder paste (produced by Senju Metal Industry Co., Ltd.; composition: Sn-3.0Ag-0.5Cu; melting point: 217° C. to 220° C.) with powder of magnetic material in a mortar. Next, using a blade coating method, samples Ex.1 to Ex.6 of a predetermined size (1 cm long by 1 cm wide by 60 μm thick) were produced on a polyimide film. The compositions of samples Ex.1 to Ex.6 are shown in Table 1.

Next, the polyimide film with sample Ex.1 formed thereon was placed at the position of the central axis of the cylindrical cavity resonator. The cavity resonator is the cavity resonator 51 described in FIG. 5. Next, a standing wave was formed in the cavity resonator in TM110 mode and sample Ex.1 was heated. The output power of the microwave was 160 W. During microwave irradiation, the temperature T of sample Ex.1 was measured using a thermocamera and the time required for the temperature T to reach a melting point TM of the solder material was measured. The rate of temperature rise was calculated by dividing the difference between the initial measurement value of the temperature T and the melting point TM by measured time requirement. The rates of temperature rise of samples Ex.2 to Ex.6 were calculated using the same technique as the one used for sample Ex. 1.

Comparison sample Re.1 with a size of 1 by 1 cm³ was produced using the solder paste alone. The rate of temperature rise of sample Re.1 was calculated using the same technique as the one used for samples Ex. 1 to Ex.6.

After the rates of temperature rise of the samples were calculated, the samples were evaluated with reference to the rate of temperature rise of sample Re. 1. Any sample with a rate of temperature rise higher than that of sample Re.1 was evaluated as “A” and any sample with a rate of temperature rise lower than that of sample Re.1 was evaluated as “F.” Evaluation results are shown in Table 1.

TABLE 1

| | | SOLDER MATERIAL | MAGNETIC MATERIAL | | RATE OF |
|---|---|---|---|---|---|
| | HEATING | (wt %) | (wt %) | | TEMPERATURE |
| | METHOD | Sn—3.0Ag—0.5Cu | Ni | Fe3O4 | RISE |
| Ex. 1 | MW_160 W | 99.9 | 0.1 | 0 | A |
| Ex. 2 | MW_160 W | 99.5 | 0.5 | 0 | A |
| Ex. 3 | MW_160 W | 99 | 1 | 0 | A |
| Ex. 4 | MW_160 W | 99.9 | 0 | 0.1 | A |
| Ex. 5 | MW_160 W | 99.5 | 0 | 0.5 | A |
| Ex. 6 | MW_160 W | 99 | 0 | 1 | A |
| Re. 1 | MW_160 W | 100 | 0 | 0 | — |

As shown in Table 1, the rates of temperature rise of all samples Ex.1 to Ex.6 were higher than the rate of temperature rise of sample Re.1. It can be seen from this that the addition of magnetic material makes samples of solder material higher in the rate of temperature rise than the comparison sample.

### 4.2 Example 2

Using the same technique as the one used for sample Ex.1, samples Ex.7 to Ex.14 were produced. The compositions of samples Ex.7 to Ex.14 are shown in Table 2. Next, using the same technique as the one used for sample Ex.1, the rates of temperature rise of samples Ex.7 to Ex.14 were calculated. Note that the output power of the microwave was 50 W. After the rates of temperature rise of the samples were calculated, the samples were evaluated with reference to the rate of temperature rise of sample Re.1. Evaluation results are shown in Table 2.

TABLE 2

| | | SOLDER | | | | | | | | | RATE OF |
|---|---|---|---|---|---|---|---|---|---|---|---|
| | MW | MATERIAL (wt %) | MAGNETIC MATERIAL (wt %) | | | | | | | | TEMPERATURE |
| | OUTPUT | Sn—3.0Ag—0.5Cu | Co | Y | Fe—Ni | Nd2O3 | Tb3O4 | Sm2O3 | Co3O4 | Fe3N | RISE |
| Ex. 7 | 50 W | 99.8 | 0.2 | | | | | | | | A |
| Ex. 8 | 50 W | 99.8 | | 0.2 | | | | | | | A |
| Ex. 9 | 50 W | 99.8 | | | 0.2 | | | | | | A |
| Ex. 10 | 50 W | 99.8 | | | | 0.2 | | | | | A |
| Ex. 11 | 50 W | 99.8 | | | | | 0.2 | | | | A |
| Ex. 12 | 50 W | 99.8 | | | | | | 0.2 | | | A |
| Ex. 13 | 50 W | 99.8 | | | | | | | 0.2 | | A |
| Ex. 14 | 50 W | 100 | | | | | | | | 0.2 | A |

As shown in Table 2, the rates of temperature rise of all samples Ex.7 to Ex.14 were higher than the rate of temperature rise of sample Re.1. It can be seen from this that the effect of increasing the rate of temperature rise is obtained regardless of the type of magnetic material. When attention was paid to the type of magnetic material, it was found that magnetic materials (Co, Fe—Ni, and Fe₃N) having ferromagnetism tend to be higher in the rate of temperature rise than are magnetic materials (Y, Nd₂O₃, Tb₃O₄, Sm₂O₃, and Co₃O₄) having paramagnetism or diamagnetism.

### 4.3 Example 3

Using low-temperature solder paste (produced by Senju Metal Industry Co., Ltd.; composition: Sn-58Bi; melting point: 139° C.), high-temperature solder paste (produced by Senju Metal Industry Co., Ltd.; composition: Sn-10Sb; melting point: 245° C. to 266° C.), and magnetic material, samples Ex.15 to Ex.36 were produced by the same technique as the one used for sample Ex.1. Comparison samples Re.2 and Re.3 were produced using the solder paste alone. The compositions of samples Ex.15 to Ex.36 and samples Re.2 and Re.3 are shown in Table 3. Next, the rates of temperature rise of the samples were calculated. After the rates of temperature rise of the samples were calculated, the samples were evaluated with reference to the rate of temperature rise of the comparison samples. Specifically, among samples Ex.15 to Ex.30, any sample with a rate of temperature rise higher than that of sample Re.2 was evaluated as “A” and any sample with a rate of temperature rise lower than that of sample Re.2 was evaluated as “F.” Samples Ex.31 to Ex.36 were evaluated in the same manner as above with reference to sample Re.3. Evaluation results are shown in Table 3.

TABLE 3

| | | | SOLDER | | MAGNETIC | | RATE OF |
|---|---|---|---|---|---|---|---|
| | | | MATERIAL | | MATERIAL | | TEMPER- |
| | MW | | (wt %) | | (wt %) | | ATURE |
| | OUTPUT | | Sn—58Bi | Sn—10Sb | Ni | Fe3O4 | RISE |
| Ex. 15 | 50 | W | 99.99 | | 0.01 | | A |
| Ex. 16 | 50 | W | 99.95 | | 0.05 | | A |
| Ex. 17 | 50 | W | 99.9 | | 0.1 | | A |
| Ex. 18 | 50 | W | 99.5 | | 0.5 | | A |
| Ex. 19 | 50 | W | 99.1 | | 0.9 | | A |
| Ex. 20 | 50 | W | 99 | | 1 | | A |
| Ex. 21 | 50 | W | 90 | | 10 | | A |
| Ex. 22 | 50 | W | 80 | | 20 | | A |
| Ex. 23 | 50 | W | 99.99 | | | 0.01 | A |
| Ex. 24 | 50 | W | 99.95 | | | 0.05 | A |
| Ex. 25 | 50 | W | 99.9 | | | 0.1 | A |
| Ex. 26 | 50 | W | 99.5 | | | 0.5 | A |
| Ex. 27 | 50 | W | 99.1 | | | 0.9 | A |
| Ex. 28 | 50 | W | 99 | | | 1 | A |
| Ex. 29 | 50 | W | 90 | | | 10 | A |
| Ex. 30 | 50 | W | 80 | | | 20 | A |
| Ex. 31 | 160 | W | | 99.9 | 0.1 | | A |
| Ex. 32 | 160 | W | | 99.5 | 0.5 | | A |
| Ex. 33 | 160 | W | | 99 | 1 | | A |
| Ex. 34 | 160 | W | | 99.9 | | 0.1 | A |
| Ex. 35 | 160 | W | | 99.5 | | 0.5 | A |
| Ex. 36 | 160 | W | | 99 | | 1 | A |
| Re. 2 | 50 | W | 100 | | | | — |
| Re. 3 | 160 | W | | 100 | | | — |

As shown in Table 3, the rates of temperature rise of all samples Ex.15 to Ex.30 were higher than the rate of temperature rise of sample Re.2. The rates of temperature rise of all samples Ex.31 to Ex.36 were higher than the rate of temperature rise of sample Re.3. It can be seen from this that the effect of increasing the rate of temperature rise is obtained regardless of the type of solder material.

### 4.4 Example 4

Using the same material as the one used for sample Ex.3, samples Ex.37 to Ex.56 with varied proportions of the magnetic material were produced by the same technique as the one used for sample Ex.1. Next, the samples were evaluated in terms of maximum temperature and cohesiveness. The maximum temperature is a maximum value of sample temperature for a period of five seconds from the start of microwave irradiation. Any sample whose maximum temperature was equal to or higher than the melting point of the solder material was evaluated as “A” and any other sample was evaluated as “F.” The cohesiveness was evaluated by visually checking the samples after melting. Any sample whose solder material was judged to have no problem in practical use in terms of cohesion was evaluated as “A.” Any sample judged to be at or above a certain level in terms of the cohesion of solder material was evaluated as “C” and any other sample was evaluated as “F.” Evaluation results are shown in Table 4.

TABLE 4

| | | SOLDER | MAGNETIC | | MAXI- | |
|---|---|---|---|---|---|---|
| | MW | MATERIAL | MATERIAL | | MUM | COHE- |
| | OUT- | (wt %) | (wt %) | | TEMPER- | SIVE- |
| | PUT | Sn—58Bi | Ni | Fe3O4 | ATURE | NESS |
| Ex. 37 | 50 W | 99.995 | 0.005 | | F | A |
| Ex. 38 | 50 W | 99.99 | 0.01 | | F | A |
| Ex. 39 | 50 W | 99.95 | 0.05 | | F | A |
| Ex. 40 | 50 W | 99.9 | 0.1 | | A | A |
| Ex. 41 | 50 W | 99.5 | 0.5 | | A | A |
| Ex. 42 | 50 W | 99.1 | 0.9 | | A | A |
| Ex. 43 | 50 W | 99 | 1 | | A | A |
| Ex. 44 | 50 W | 95 | 5 | | A | A |
| Ex. 45 | 50 W | 90 | 10 | | A | C |
| Ex. 46 | 50 W | 80 | 20 | | A | C |
| Ex. 47 | 50 W | 99.995 | | 0.005 | F | A |
| Ex. 48 | 50 W | 99.99 | | 0.01 | F | A |
| Ex. 49 | 50 W | 99.95 | | 0.05 | F | A |
| Ex. 50 | 50 W | 99.9 | | 0.1 | A | A |
| Ex. 51 | 50 W | 99.5 | | 0.5 | A | A |
| Ex. 52 | 50 W | 99.1 | | 0.9 | A | A |
| Ex. 53 | 50 W | 99 | | 1 | A | A |
| Ex. 54 | 50 W | 95 | | 5 | A | A |
| Ex. 55 | 50 W | 90 | | 10 | A | C |
| Ex. 56 | 50 W | 80 | | 20 | A | C |

As shown in Table 4, the maximum temperatures of samples Ex.40 to Ex.46 and Ex.50 to Ex.56 reached the melting point within five seconds from the start of microwave irradiation. On the other hand, the maximum temperatures of samples Ex.37 to Ex.39 and Ex.47 to Ex.49 did not reach the melting point within five seconds from the start of microwave irradiation. It can be seen from this that when the proportion of the magnetic material is small, the solder material is difficult to melt in a short time. Thus, the maximum temperature was evaluated by changing the output conditions of the microwave, and it was found that by increasing output, the maximum temperature can be adjusted to a desired value. Therefore, it was also found that it is desirable to change the microwave output according to the type and proportion of magnetic material.

As shown in Table 4, samples Ex.37 to Ex.44 and Ex.47 to Ex.54 were judged to have no problem in practical use in terms of the cohesion of solder material. On the other hand, samples Ex.45, Ex.46, Ex.55, and Ex.56 were judged to be at or above a certain level in terms of the cohesion of solder material. Thus, it was found that when the proportion of the magnetic material is 5% by mass or below, the effect of increasing the rate of temperature rise can be obtained while reducing the impact on the original joining function of the solder.

### REFERENCE SIGNS LIST

10 Solder preform
11 Solder layer
12 Magnetic layer
20 Solder ball
21 Solder particle
22 Magnetic particle
30 Solder paste
31 Solder particle
32 Magnetic particle
33 Flux
40 Induction heating device
41 Heating coil
42 Inverter circuit
43 Control circuit
44, 53 Conveyer
45, 56 Temperature sensor
50 Microwave heating device
51 Cavity resonator
52 Microwave feeder
54 Controller
55 Electromagnetic wave sensor
EC Electronic component
PB Printed board
SD Solder

1-8. (canceled)

9. A Magnetic-field melting solder that melts by action of an AC magnetic field, the magnetic-field melting solder comprising:
solder material; and
magnetic material composing of ferrite or Ni, a proportion of the magnetic material to the entire magnetic-field melting solder being 0.005 to 5% by weight.

10. The magnetic-field melting solder according to claim 9, wherein an upper limit of the proportion is 0.9% by weight.

11. The magnetic-field melting solder according to claim 9, wherein a lower limit of the proportion is 0.1% A by weight.

12. The magnetic-field melting solder according to claim 9, further comprising:
a solder layer containing the solder material; and
a magnetic layer containing the magnetic material by being provided on a surface of the solder layer.

13. The magnetic-field melting solder according to claim 9, further comprising:
solder particles containing the solder material; and
magnetic particles containing the magnetic material by being provided inside the solder particles.

14. The magnetic-field melting solder according to claim 9, further containing flux.

15. A joining method using the magnetic-field melting solder that melts by action of an AC magnetic field, the magnetic-field melting solder comprising:
solder material; and
magnetic material composing of ferrite or Ni, a proportion of the magnetic material to the entire magnetic-field melting solder being 0.005 to 5% by weight, the method comprising:
providing the magnetic-field melting solder between an electrode on a substrate and an electrode of an electronic component; and
joining together the electrode on the substrate and the electrode of the electronic component by generating an AC magnetic field around the substrate and thereby melting the magnetic-field melting solder.
